(19) United States
(12) Patent Application Publication
(10) Pub. No.: US 2023/0146757 A1
(43) Pub. Date: May 11, 2023

(54) METHOD AND APPARATUS FOR FORMING SILICON CARBIDE-CONTAINING FILM

(71) Applicant: Tokyo Electron Limited, Minato-ku, Tokyo (JP)

(72) Inventors: Makoto FUJIKAWA, Nirasaki City, Yamanashi (JP); Susumu YAMAUCHI, Nirasaki City, Yamanashi (JP)

(21) Appl. No.: 17/906,897

(22) PCT Filed: Mar. 12, 2021
(86) PCT No.: PCT/JP2021/010193

§ 371 Date: Sep. 21, 2022

(30) Foreign Application Priority Data
Mar. 26, 2020 (JP) 2020-056390

(51) Int. Cl. H01L 21/02; H01J 37/32; H01L 21/31; C23C 16/32; C23C 16/455

(52) U.S. Cl. CPC H01L 21/02167; H01J 37/32449; H01J 37/32724; H01L 21/02274; H01L 21/0228; H01L 21/31; C23C 16/325; C23C 16/45553; C23C 16/45536; H01J 2237/332

(57) ABSTRACT

A method of forming a silicon carbide-containing film on a substrate, includes: heating the substrate; supplying a carbon precursor gas containing an organic compound having an unsaturated carbon bond to the heated substrate; supplying a silicon precursor gas containing a silicon compound to the heated substrate; laminating, on the substrate, a silicon carbide-containing layer to be turned into the silicon carbide-containing film by allowing the organic compound having the unsaturated carbon bond to thermally react with the silicon compound; and supplying plasma to the silicon carbide-containing layer.

### TECHNICAL FIELD

The present disclosure relates to a method and apparatus for forming a silicon carbide-containing film.

### BACKGROUND

In a multi-gate type fin-field effect transistors (Fin-FET) or the like, which is a semiconductor element, an integration degree thereof is becoming increasingly higher so that plural types of films may be exposed inside an opening formed in a hard mask. Therefore, there is an increasing need for a hard mask material capable of etching a desired film with high selectivity between films exposed in a microswcopic opening. As a material satisfying such a need, the present inventors have developed a technology for forming a silicon carbide-containing film (hereinafter, referred to as a “SiC film”).

Patent Document 1 discloses, in forming a SiC:H film, a technique of forming the SiC:H film having a low specific dielectric constant by repeating growth and stopping the growth of the film to divisionally form and grow the film multiple times. In addition, Patent Document 1 discloses that the SiC:H film having a low dielectric constant is obtained by reducing a film thickness to be grown in one round of growth.

### PRIOR ART DOCUMENT

### Patent Document

Patent Document 1: Japanese Laid-Open Patent Publication No. 2003-124209

### SUMMARY

The present disclosure provides a technique for forming a silicon carbide-containing film which is difficult to oxidize.

The present disclosure relates to a method of forming a silicon carbide-containing film on a substrate, including: heating the substrate; supplying a carbon precursor gas containing an organic compound having an unsaturated carbon bond to the heated substrate; supplying a silicon precursor gas containing a silicon compound to the heated substrate; laminating, on the substrate, a silicon carbide-containing layer to be turned into the silicon carbide-containing film by allowing the organic compound having the unsaturated carbon bond to thermally react with the silicon compound; and supplying plasma to the silicon carbide-containing layer.

According to the present disclosure, it is possible to form a silicon carbide-containing film that is difficult to oxidize.

### BRIEF DESCRIPTION OF DRAWINGS

FIG. 1 is a vertical cross-sectional side view illustrating an example of a film forming apparatus of the present disclosure.

FIG. 2 illustrates an example of a chemical reaction formula used in a film forming method of the present disclosure.

FIG. 3 illustrates an example of a reaction model related to the chemical reaction formula.

FIG. 4 is a time chart illustrating an example of the film forming method.

FIGS. 5A and 5B illustrate structural formulas showing other examples of carbon precursors.

FIG. 6 illustrates an example of another chemical reaction formula used in the film forming method.

FIG. 7 illustrates an example of a reaction model related to another chemical reaction formula.

FIG. 8 is an explanatory view illustrating variations of carbon precursors.

FIG. 9 is an explanatory view illustrating variations of silicon precursors.

FIG. 10 is a time chart illustrating another example of the film forming method.

FIG. 11 is a plan view illustrating another example of the film forming apparatus.

FIG. 12 is a vertical cross-sectional side view illustrating yet another example of the film forming apparatus.

FIG. 13 is a characteristic diagram showing an evaluation result of the film forming method.

FIG. 14 is a characteristic diagram showing an evaluation result of the film forming method.

FIG. 15 is a characteristic diagram showing an evaluation result of the film forming method.

FIG. 16 is a characteristic diagram showing an evaluation result of the film forming method.

FIG. 17 is a characteristic diagram showing an evaluation result of the film forming method.

### DETAILED DESCRIPTION

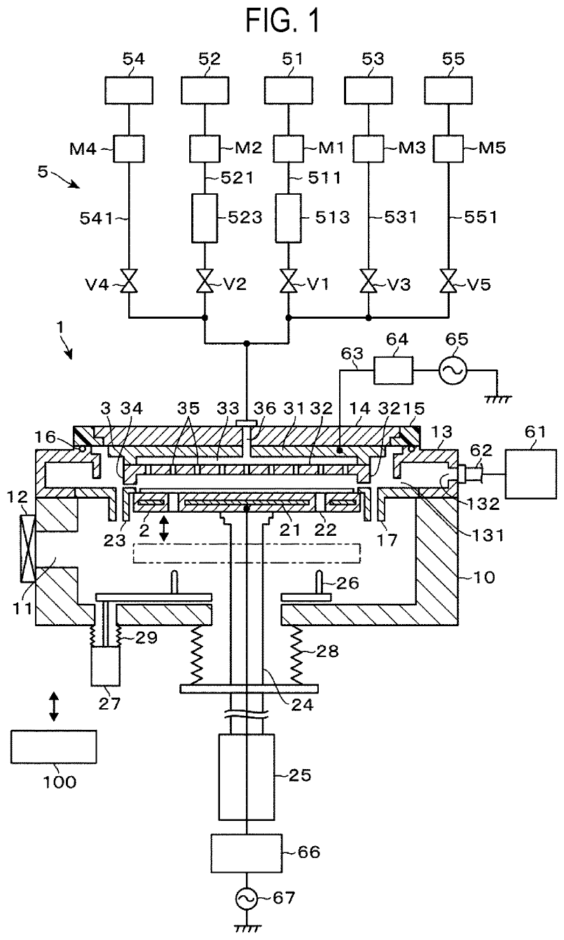

A single-wafer-type film forming apparatus, which is an embodiment of an apparatus (hereinafter, referred to as a “film forming apparatus”) for carrying out a method (hereinafter referred to as a “film forming method”) of forming a silicon carbide-containing film of the present disclosure, will be described with reference to FIG. 1. A film forming apparatus 1 includes a processing container 10 that accommodates a substrate, for example, a semiconductor wafer (hereinafter, referred to as a “wafer”) W. The processing container 10 is formed of a metal such as aluminum (Al) in a substantially cylindrical shape. A loading/unloading port 11 through which the wafer W is loaded or unloaded is formed in a sidewall of the processing container 10 and is opened/closed by a gate valve 12.

For example, an annular exhaust duct 13 having a rectangular shape in a cross section is disposed on an upper portion of the sidewall of the processing container 10. The exhaust duct 13 is provided with a slit 131 along an inner peripheral surface thereof. An exhaust port 132 is formed in an outer wall of the exhaust duct 13. A ceiling wall 14 is provided on an upper surface of the exhaust duct 13 to close an upper opening of the processing container 10 via an insulating member 15. A gap between the exhaust duct 13 and the insulating member 15 is hermetically sealed with a seal ring 16.

A stage 2 for horizontally supporting the wafer W is provided inside the processing container 10. The stage 2 is made of a ceramic material such as aluminum nitride (AlN), or a metal material such as aluminum or nickel alloy in a disk shape. In this example, a heater 21 which constitutes a heater for heating the wafer W is embedded in the stage 2. An outer peripheral region and a side surface of the upper surface of the stage 2 are covered with a cover member 23 made of ceramic such as alumina.

The stage 2 is connected to a lifting mechanism 25 provided below the processing container 10 via a support member 24, and is configured to be moved up and down between a processing position illustrated in FIG. 1 and a delivery position for the wafer W, which is indicated by a double-dot chain line, below the processing position. In FIG. 1, reference numeral 17 indicates a partition member for partitioning the interior of the processing container 10 into upper and lower portions when the stage 2 is raised to the processing position. Three support pins 26 (only two of which are illustrated) are provided below the stage 2 inside the processing container 10 to be movable up and down by a lifting mechanism 27 provided below the processing container 10. The support pins 26 are inserted into respective through-holes 22 of the stage 2 located at the delivery position and are configured to move upward and downward with respect to the upper surface of the stage 2. The support pins 26 are used to deliver the wafer W between a transfer mechanism (not illustrated) and the stage 2. Reference numerals 28 and 29 in the figure denote bellows which is configured to isolate an internal atmosphere of the processing container 10 from ambient air and to be flexible with the vertical movement of the support pins 26. An RF power source (a radio-frequency power supply) 67 is connected to the stage 2 via a matcher 66 so that radio-frequency power for plasma attraction can be supplied to the stage 2. The radio-frequency power for plasma attraction may be omitted.

The processing container 10 is provided with a shower head 3 for supplying a process gas in the form of a shower into the process container 10 so as to face the stage 2. The shower head 3 includes a main body portion 31 fixed to the ceiling wall 14 of the processing container 10, and a shower plate 32 connected under the main body portion 31, and the interior thereof forms a gas diffusion space 33. An annular protrusion 34 protruding downward is formed at a peripheral portion of the shower plate 32, and gas discharge holes 35 are formed in an inner flat surface of the annular protrusion 34. A gas supply system 5 is connected to the gas diffusion space 33 via a gas introduction hole 36.

The gas supply system 5 includes a carbon precursor supplier configured to supply a gas of carbon precursor to the processing container 10, and a silicon precursor supplier configured to supply a silicon precursor gas. The carbon precursor supplier includes a source 51 of the gas of carbon precursor and a gas supply path 511. The gas supply path 511 is provided with a flow rate regulator M1, a storage tank 513, and a valve V1 from the upstream side.

The carbon precursor contains an organic compound having an unsaturated carbon bond. As an example, bis(trimethylsilyl)acetylene (BTMSA) having a triple bond is used as the carbon precursor. Hereinafter, the gas of carbon precursor may be referred to as a carbon precursor gas or BTMSA gas. The carbon precursor gas supplied from the source 51 is temporarily stored in the storage tank 513, boosted to a predetermined internal pressure of the storage tank 513, and then supplied into the processing container 10. BTMSA is liquid at room temperature, and a gas obtained by heating the BTMSA is supplied to and stored in the storage tank 513. The supply and cutoff of the carbon precursor gas from the storage tank 513 to the processing container 10 are carried out by opening and closing the valve V1.

The silicon precursor supplier includes a source 52 of a gas of silicon precursor, and a gas supply path 521. The gas supply path 521 is provided with a flow rate regulator M2, a storage tank 523, and a valve V2 from the upstream side. The silicon precursor contains a silicon compound. As an example, disilane (Si₂H₆) is used as the silicon precursor. Here, the gas of silicon precursor may be referred to as a silicon precursor gas or a disilane gas. The silicon precursor gas supplied from the source 52 is temporarily stored in the storage tank 523, boosted to a predetermined internal pressure of the storage tank 523, and then supplied into the processing container 10. The supply and cutoff of the silicon precursor gas from the storage tank 523 to the processing container 10 are carried out by opening and closing the valve V2.

In addition, the gas supply system 5 includes sources 53 and 54 of an inert gas such as an argon (Ar) gas. In this example, the Ar gas supplied from the source 53 is used as a purge gas for carbon precursor gas. The source 53 is connected to the downstream side of the valve V1 in the gas supply path 511 of the carbon precursor gas via a gas supply path 531 provided with a flow rate regulator M3 and a valve V3 from the upstream side.

The Ar gas supplied from the source 54 is used as a purge gas for silicon precursor gas. The source 54 is connected to the downstream side of the valve V4 in the gas supply path 521 of the silicon precursor gas via a gas supply path 541 provided with a flow rate regulator M4 and a valve V4 from the upstream side. The supply and cutoff of the Ar gas to the processing container 10 is performed by opening and closing the valves V3 and V4.

In addition, the gas supply system 5 is provided with a source 55 of a hydrogen (H₂) gas which is a gas for plasma formation. The H₂ gas source 55 is connected to, for example, the downstream side of the valve V1 in the gas supply path 511 of the carbon precursor gas via a gas supply path 551 provided with a flow rate regulator M5 and a valve V5 from the upstream side.

An RF power supply (a radio-frequency power supply) 65 for plasma generation is connected to the shower head 3 via a matcher 64. The film forming apparatus of the present disclosure is configured as a capacitively coupled plasma processing apparatus that supplies a gas to be excited into the processing container 10 and applies radio-frequency power between the shower head 3 constituting an upper electrode and the stage 2 constituting a lower electrode to generate plasma. The sources 53 and 54 of the argon (Ar) gas, the source 55 of the H₂ gas, the gas supply paths 531, 541, and 551, and the radio-frequency power supplies 65 and 67, which apply the radio-frequency power to the shower head 3 and the stage 2, respectively, constitute a plasma forming part.

The processing container 10 is connected to a vacuum exhaust path 62 via an exhaust port 132. A vacuum exhaust part 61, which is configured to execute vacuum exhaustion of a gas inside the processing container 10 and includes, for example, a pressure regulating valve or a vacuum pump, is provided on the downstream side of the vacuum exhaust path 62.

A controller 100 is constituted with, for example, a computer, and is provided with a data processor including a program, a memory, and a CPU. The program incorporates commands (respective steps) such that the controller 100 sends control signals to each part of the film forming apparatus 1 to execute a film forming process of a SiC film to be described later. The program is stored in a storage part such as a computer storage medium such as a flexible disk, a compact disk, a hard disk, a magneto-optical disk (MO), or the like, and is installed in the controller 100.

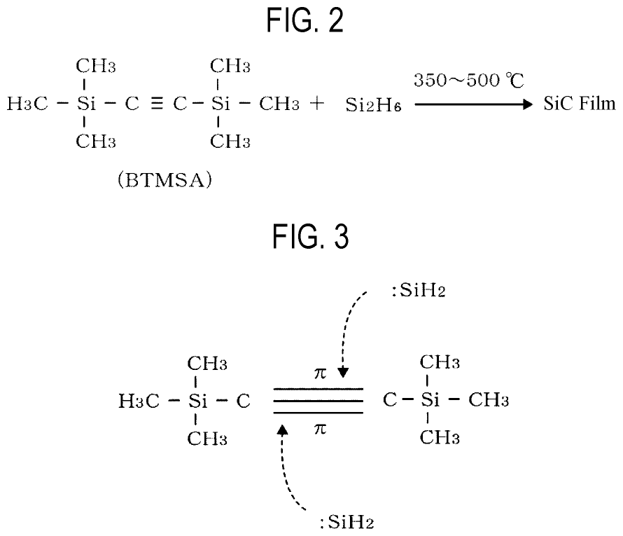

Next, the film forming method carried out by the film forming apparatus 1 will be described. The film forming method of the present disclosure forms a SiC film, which is a silicon carbide-containing film, by a thermal reaction at, for example, 500 degrees C. or lower, with the carbon precursor gas and the silicon precursor gas. FIG. 2 illustrates an example in which BTMSA, which is a carbon precursor and has a triple bond, and disilane, which is a silicon precursor, thermally react with each other at a temperature in a range of, for example, 350 degrees C. or higher and 500 degrees C. or lower.

A mechanism that is capable of forming the SiC film by such a thermal reaction at a low temperature may be considered by using Reaction Model 1 illustrated in FIG. 3. Disilane is thermally decomposed by heating at a temperature near 400 degrees C. to generate a SiH₂ radical having an unpaired electron in the Si atom, wherein the SiH₂ radical has an empty p-orbital. In Reaction Model 1, this empty p-orbital acts as an electrophile that attacks a π bond of an unsaturated carbon bond of electron-rich BTMSA and acts on the triple bond of BTMSA. Further, Reaction Model 1 is a model in which C forming the triple bond reacts with Si of the SiH₂ radical to form a SiC bond.

The π bond of the BTMSA triple bond has a smaller bonding force than a σ bond. Thus, it is presumed that, when a SiH₂ radical attacks this π bond, a thermal reaction proceeds even at a temperature of 500 degrees C. or lower, thereby forming a SiC bond. Further, Reaction Model 1 presumes the reason why the formation of SiC film at a low temperature, which has been considered difficult in the related art, is enabled and does not limit an actual reaction route. Another reaction path may be used in forming the SiC film as long as the SiC film can be formed at a temperature of 500 degrees C. or lower without using plasma.

On the other hand, when the SiC film is formed at such a low temperature, the SiC film may have a tendency to be easily oxidized. As described above, in the film forming process of the present disclosure, a SiH₂ radical attacks a 7C bond of a triple bond to generate a SiC bond. When it is possible to form a highly pure SiC film having few residual functional groups, other than carbon atoms and silicon atoms contained in each precursor, and few dangling bonds, the SiC film is difficult to oxidize. The highly pure SiC film refers to an amorphous film in which a Si—C bond forming rate is high. On the other hand, it is presumed that, when there are many functional groups and dangling bonds remaining in a SiC film, the SiC film is easily oxidized since oxygen is easily bonded to these functional groups and dangling bonds. When the wafer W, on which such an easy-to-oxidize SiC film is formed, is taken out from the film forming apparatus 1 and transferred in an ambient environment, the SiC film may be oxidized and may undergo a property change.

In order to prevent such oxidization of the SiC film, a method of suppressing contact with oxygen to suppress the oxidization of the SiC film by forming an amorphous Si sealing film on an upper surface of the SiC film may also be considered. However, there is a problem in that a process of removing the sealing film is required in a subsequent process, the number of processes is increased, and additional equipment for removing the sealing film is required.

Therefore, in the film forming method according to the present embodiment, each time a thickness of a SiC layer, which is a silicon carbide-containing layer formed on the wafer W, reaches a certain thickness, plasma (in this example, plasma of a mixed gas of an Ar gas and a H₂ gas) is applied to the SiC layer. By supplying the plasma to the SiC layer in this way, it is possible to promote elimination of unnecessary functional groups and bonding between dangling bonds, and to form a stable SiC film that is difficult to oxidize.

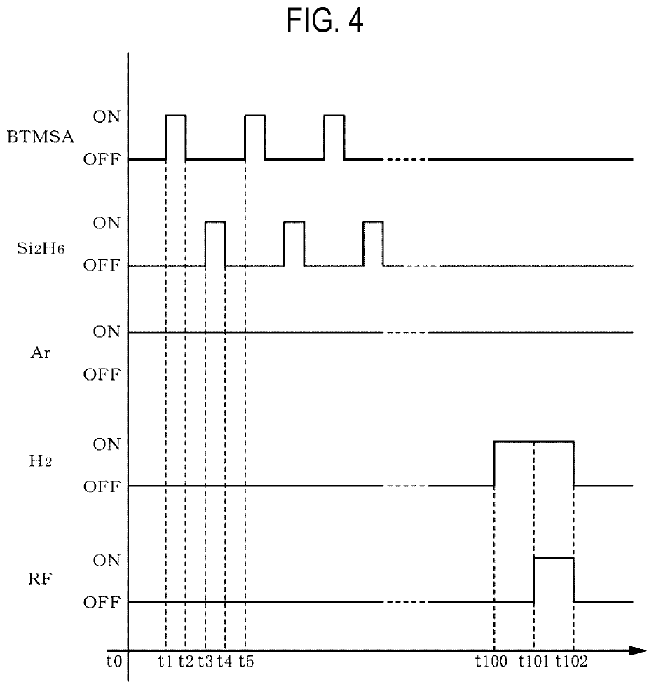

Next, an example of the film forming method of the present disclosure will be described with reference to a time chart of FIG. 4. FIG. 4 illustrates a timing of initiating and cutting off the supply of each of the BTMSA gas, the disilane gas, the Ar gas, and the H₂ gas, and a timing of applying radio-frequency power from the radio-frequency power supply 65 or both the radio-frequency power supplies 65 and 67 (hereinafter, the reference numerals “65 and 67” may be merely indicated). For the BTMSA gas, the disilane gas, the Ar gas, and the H₂ gas, “ON” on the vertical axis indicates the supply state, and “OFF” on the vertical axis indicates the cutoff state. In addition, for RF, “ON” means the state in which the radio-frequency power supply 65 or the radio-frequency power supplies 65 and 67 are set to “ON” and radio-frequency power is applied to the shower head 3 or the shower head 3 and the stage 2.

The outline of the film forming process of this example will be described with reference to FIG. 4. First, a process of supplying the BTMSA gas as a carbon precursor to the heated wafer W is performed. This makes it possible to adsorb BTMSA on the wafer W. Subsequently, a process of supplying the disilane gas as a silicon precursor to the heated wafer W is performed. As a result, BTMSA adsorbed on the wafer W and disilane are allowed to thermally react with each other. Further, the process of supplying the carbon precursor to the wafer W and the process of supplying the silicon precursor to the wafer W are alternately repeated multiple times so that SiC layers are laminated by an atomic layer deposition (ALD) method.

In the film forming process, first, a process of loading the wafer W into the processing container 10, and closing the gate valve 12 of the processing container 10 to accommodate the wafer W in the processing container 10, is performed. Then, the wafer W is heated by the heater 21, and the interior of the processing container 10 is evacuated by the vacuum exhaust part 61. The stage 2 is raised to be located at the processing position.

In addition, the valves V3 and V4 for Ar, which is a purge gas, are opened to supply Ar from the sources 53 and 54 into the processing container 10 at a total flow rate of, for example, 300 sccm (time t0). The Ar gas is introduced into the processing container 10 via the shower head 3, flows toward the exhaust port 132 on the side of the wafer W placed on the stage 2 located at the processing position, and is discharged from the processing container 10 via the vacuum exhaust path 62.

Subsequently, at time t1, the valve V1 is opened to supply the BTMSA gas, which is a carbon precursor, to the processing container 10 so that the BTMSA is adsorbed on the wafer W. With the operation of opening the valve V, the BTMSA gas stored in the storage tank 513 is supplied into the processing container 10 in a short period of time. At this time, the wafer W is heated by the heater 21 to a temperature in the range of 350 degrees C. or higher and 500 degrees C. or lower, for example, 410 degrees C. By the above-described process, it is possible to adsorb the BTMSA on the surface of the wafer W.

Then, the valve V1 is turned OFF at time t2 after a lapse of a set time from time t1. As a result, the supply of the BTMSA gas into the processing container 10 is stopped, while the supply of the Ar gas, which is a purge gas, is continued, so that the BTMSA gas remaining in the processing container 10 is replaced with the Ar gas.

Subsequently, at time t3, the valve V2 is opened to supply the disilane gas, which is a silicon precursor, to allow BTMSA adsorbed on the wafer W to react with disilane. With the operation of opening the valve V2, the disilane gas stored in the storage tank 523 is supplied into the processing container 10 in a short period of time. The disilane gas is supplied for a predetermined period of time (e.g., 1 second) until the valve V2 is closed and the supply of the disilane gas is stopped at time t4.

The disilane gas introduced from the shower head 3 comes into contact with the BTMSA adsorbed on the wafer W while flowing through the interior of the processing container 10 toward the exhaust port 132, whereby a thermal reaction proceeds to form SiC. By turning OFF the valve V2, the supply of the disilane gas into the processing container 10 is stopped, while the supply of the Ar gas, which is a purge gas, is continued, so that the disilane gas remaining in the processing container 10 is replaced with the Ar gas.

Subsequently, the supply of the BTMSA gas, which is a carbon precursor, is initiated again at time t5. In this way, by alternately repeating multiple times the process of supplying BTMSA to the wafer W and the process of supplying disilane to the wafer W on which the BTMSA is adsorbed and allowing BTMSA to thermally react with disilane in the method described above, a process of laminating a SiC layer is performed.

Subsequently, the process of supplying BTMSA to the wafer W and the process of supplying disilane to the wafer W are repeated a predetermined number of times in advance. As a result, the SiC layer having a film thickness of, for example, 0.5 nm, is formed on the surface of the wafer W.

Thereafter, instead of supplying the BTMSA gas and the disilane gas, the supply of the Ar gas to the processing container 10 is continued so that the internal atmosphere of the processing container 10 is replaced with an Ar gas atmosphere. At time t100, the valve V5 is opened to supply the H₂ gas, which is a gas for plasma formation, to the processing container 10 at a flow rate of, for example, 2,000 sccm.

Thereafter, radio-frequency power is applied by the radio-frequency power supply 65 or the radio-frequency power supplies 65 and 67 at time t101. As a result, the Ar gas and the H₂ gas inside the processing container 10 are excited to form plasma. The plasma of these gases is supplied to the SiC layer formed on the wafer W. As a result, as described above, the plasma promotes elimination of unnecessary functional groups and bonding between dangling bonds, so that a highly pure SiC layer is formed in the SiC layer. Then, at time t102, the supply of the radio-frequency power is stopped and the valve V5 is closed to stop the supply of the H₂ gas.

After performing the process of supplying plasma to the SiC layer, the process of supplying BTMSA to the wafer W and the process of supplying disilane to the wafer W are alternately repeated multiple times. In this way, by alternately performing the process of laminating the SiC layer having a predetermined thickness and the process of supplying the plasma of the H₂ gas to the SiC layer, it is possible to laminate a highly pure SiC layer and to form a SiC film having good film quality.

According to the method of forming the SiC film (silicon carbide film) according to the above-described embodiment, for example, the BTMSA gas, which is a carbon precursor, is supplied to the heated wafer W to be adsorbed on the wafer W, and then disilane is supplied to the wafer W. By supplying plasma to the SiC layer laminated in this way, it is possible to obtain a SiC layer that is difficult to oxidize. In addition, by laminating this SiC layer, it is possible to form a SiC film that is difficult to oxidize. With the film forming method according to the present embodiment, it is possible to form a highly pure SiC film. Thus, a dense film having a high density can be formed as illustrated in Examples to be described later.

Here, as illustrated in Examples to be described later, it is possible to form a SiC film that is difficult to oxidize even when plasma formed substantially by the Ar gas is supplied to the SiC layer. Therefore, the plasma supplied to the SiC layer is not limited to the above-mentioned mixed gas of the Ar gas and the H₂ gas. For example, a noble gas such as the Ar gas or the He gas may be excited alone to form plasma. In addition, the H₂ gas may be excited alone to form plasma.

Further, when supplying plasma to the SiC layer, as the SiC layer becomes thinner, the SiC bonds can be more reliably formed. Therefore, it is preferable to repeat the process of supplying the carbon precursor and the process of supplying the silicon precursor to supply the plasma to the SiC layer at a time at which the film thickness becomes 1 nm or less.

Here, the SiC film formed by allowing the carbon precursor and the silicon precursor to thermally react with each other at a relatively low temperature of 350 degrees C. or higher and 500 degrees C. or lower through the ALD method is of high quality, and has properties suitable for a hard mask material, an insulating film, a low dielectric constant film, or the like. In a case in which a SiC film is used for a transistor of a semiconductor element, it may be required that an allowable temperature during the film forming process be 500 degrees C. or lower in order to suppress the diffusion of metal from a metal wiring layer. Meanwhile, even if a film can be formed at a low temperature of 400 degrees C. or lower, a method of forming a SiC film with plasma may cause a problem because other films and wiring layers constituting the semiconductor element may be greatly damaged due to the plasma. Therefore, it is effective to be able to form a SiC film at a temperature of 500 degrees C. or lower without using plasma by the film forming method of the present disclosure, which leads to the expansion of applications of the SiC film. In addition, a modification process is performed with hydrogen plasma each time a predetermined film thickness is obtained without using plasma when forming a SiC film. This shortens a time for using plasma, which makes it possible to effectively suppress the damage.

In addition, for example, in the process of supplying the BTMSA gas into the processing container 10, the vacuum exhaust inside the processing container 10 may be restricted so that the BTMSA gas stays inside the processing container 10. For the restriction of the vacuum exhaust, for example, the vacuum exhaust is primarily restricted by temporarily setting the pressure regulating valve of the vacuum exhaust part 61 in a closed state. For example, in the time chart illustrated in FIG. 4, the supply of the BTMSA gas is stopped at time t2, and the temporary restriction of the vacuum exhaust is initiated. With this configuration, it is possible to cause the BTMSA gas to stay inside the processing container 10. This makes it possible to promote the chemisorption of BTMSA on the surface of the wafer, thus forming a SiC film having good film quality and improving the film forming rate.

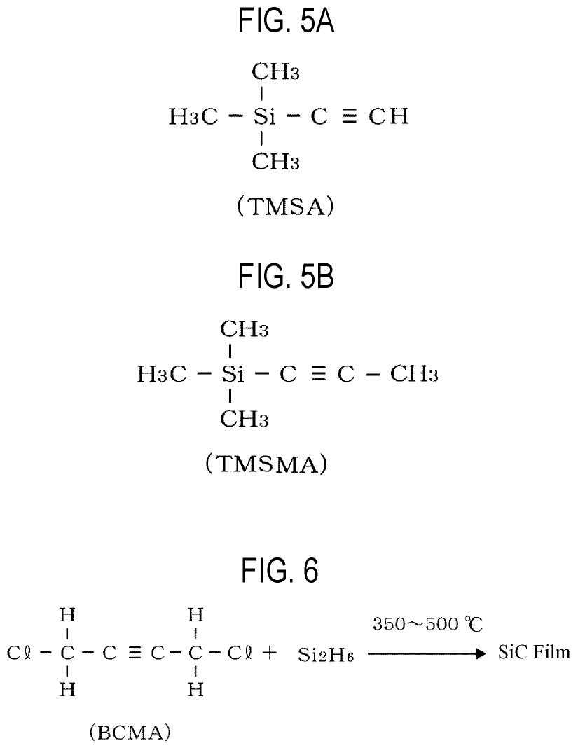

Subsequently, another example of the carbon precursor containing an organic compound having an unsaturated carbon bond will be described with reference to FIGS. 5A and 5B to FIG. 8. The carbon precursor illustrated in FIG. 5A is trimethylsilylacetylene (TMSA) having a triple bond. The carbon precursor illustrated in FIG. 5B is trimethylsilylmethyl acetylene (TMSMA) having a triple bond. A SiC film may also be formed by allowing the TMSA gas and the TMSMA gas to thermally react with the silicon precursor, for example, the disilane gas, at a temperature in the range of 300 degrees C. or higher and 500 degrees C. or lower.

In these TMSA and TMSMA as well, a SiH₂ radical having an empty p-orbital and obtained by thermal decomposition of disilane attacks a 7C bond of a triple bond. Further, it is presumed that the empty p-orbital acts on the triple bond of TMSA and TMSMA, and C of the triple bond reacts with Si of the SiH₂ radical to form a SiC bond.

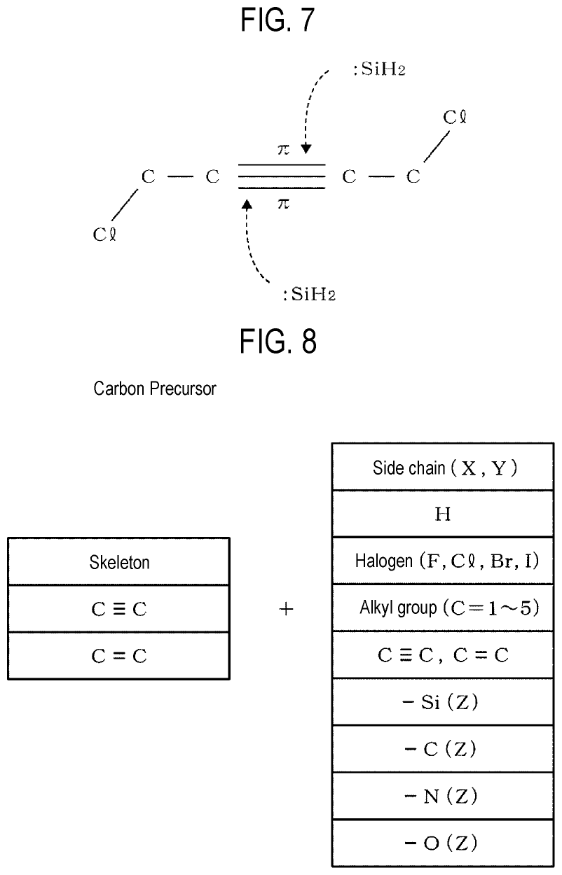

Further, the carbon precursor illustrated in FIG. 6 is bis(chloromethyl)acetylene (BCMA) having a triple bond, which is an unsaturated carbon bond, and containing a halogen. FIG. 6 illustrates an example in which the BCMA gas and the silicon precursor, for example, the disilane gas, thermally react with each other at a temperature in the range of 350 degrees C. or higher and 500 degrees C. or lower. Regarding this thermal reaction, it is presumed that Reaction Model 1 illustrated in FIG. 3 and Reaction Model 2 illustrated in FIG. 7 proceed simultaneously. Reaction Model 2 has nucleophilicity in which BCMA is polarized by having a halogen group (Cl group) and the positive polarization site (σ+) of a SiH₂ radical attacks the negative polarization site (σ−) of a halogen group. In this way, the SiH₂ radical reacts with C at a molecular end to which Cl is bonded, forming a SiC bond.

The carbon precursor containing an organic compound having an unsaturated carbon bond is not limited to the above-mentioned BTMSA, TMSA, TMSMA, and BCMA. Another carbon precursor may be used as long as it thermally reacts with the silicon precursor at a temperature of 500 degrees C. or lower to form a SiC film. As the carbon precursor, a combination of skeletons and side chains illustrated in FIG. 8 may be used. The skeleton of the carbon precursor is an unsaturated bond portion of an organic compound, and may be, for example, an unsaturated carbon bond of a triple bond or a double bond of C. The side chain of the carbon precursor is a portion that is bonded to the skeleton. Assuming that the skeleton is a triple bond, the side chain that is bonded to one C is X, and the side chain that is bonded to another C is Y. These side chains X and Y may be the same as or different from each other.

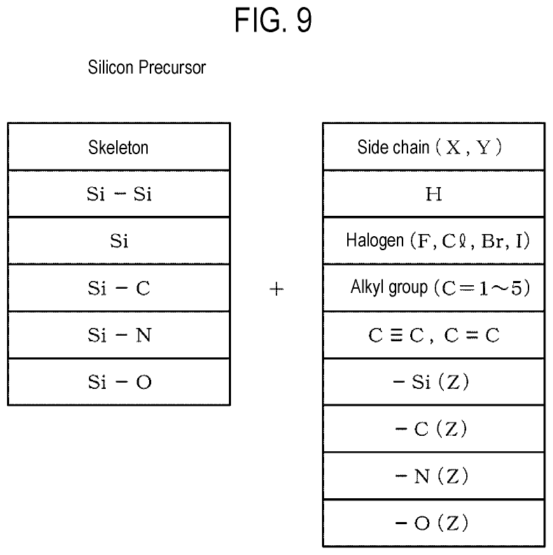

Examples of the side chains may include hydrogen (H) atoms, halogens, alkyl groups with a C number of 5 or less, triple bonds of C, double bonds of C, Si(Z), C(Z), N(Z), O(Z), and the like. In tables illustrating variations in side chains of FIGS. 8 and 9, Si(Z), C(Z), N(Z), and O(Z) are substances in which the sites bonded to C of the skeleton are Si, C, N, and O, respectively, and (Z) indicates an arbitrary atomic group.

As the silicon precursor, a combination of the skeletons and the side chains illustrated in FIG. 9 may be used. The skeleton of the silicon precursor is a Si—Si bond in terms of disilane. The side chain of the silicon precursor is a portion that is bonded to the skeleton. Assuming that the skeleton is Si—Si, the side chain X that is bonded to one Si and the side chain Y bonded to the other Si may be the same as or different from each other. Examples of the skeleton may include Si—Si, Si, Si—C, Si—N, Si—O, and the like. Examples of the side chain may include hydrogen atoms, halogens, alkyl groups with a C number of 5 or less, triple bonds of C, double bonds of C, Si(Z), C(Z), N(Z), O(Z), and the like. Examples of the silicon precursor that thermally decomposes at a temperature of 500 degrees C. or lower to generate SiH₂ radicals may include monosilane (SiH₄), trisilane (Si₃H₈), and the like, in addition to disilane.

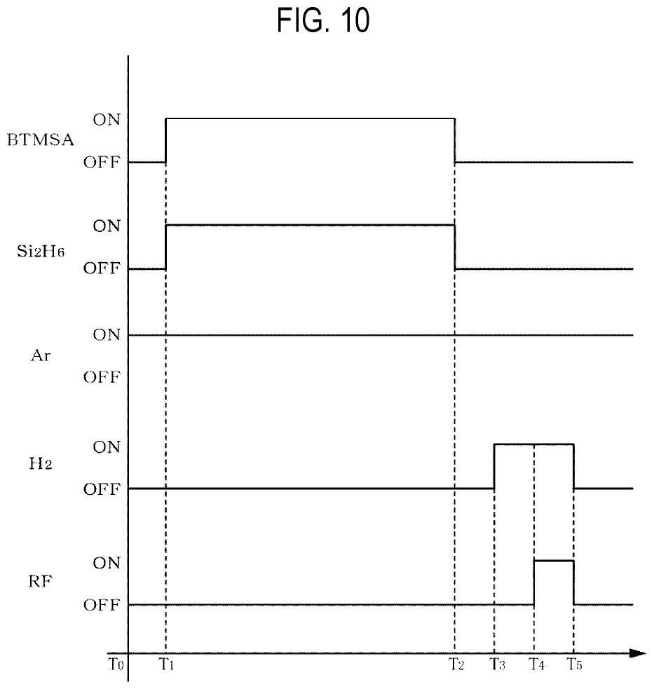

Next, another example of the film forming method carried out by the above-mentioned film forming apparatus will be described with reference to FIG. 10. FIG. 10 is a time chart illustrating a timing of initiating and stopping the supply of each of the BTMSA gas, the disilane gas, the Ar gas, and the H₂ gas, and a timing of the radio-frequency power supply 65 or the radio-frequency power supplies 65 and 67.

In this example, a SiC layer is formed on the wafer W by a chemical vapor deposition (CVD) method in which the process of supplying the BTMSA gas, which is a carbon precursor gas, and the process of supplying the disilane gas, which is a silicon precursor, are performed in a parallel (simultaneous) manner. Specifically, in the state in which the Ar gas is supplied into the processing container 10, the valves V1 and V2 are opened at time T1 to initiate the supply of the BTMSA gas and the disilane gas, and the valves V1 and V2 are closed at time T2 to stop the supply of the BTMSA gas and the disilane gas. As a result, a reaction between BTMSA and disilane occurs inside the processing container 10, so that SiC, which is a reaction product, is gradually deposited on the surface of the wafer W, forming a SiC layer.

Then, when the supply of the BTMSA gas and the disilane gas is stopped at time T2, the interior of the processing container 10 is purged with the Ar gas, and the formation of the SiC layer is stopped. In addition, at time T3, the valve V5 is opened to supply the H₂ gas, which is a gas for plasma formation, to the processing container 10. Thereafter, radio-frequency power is applied by the radio-frequency power supply 65 or the radio-frequency power supplies 65 and 67 from time T4. As a result, a mixed gas of the Ar gas continuously supplied into the processing container 10 and the H₂ gas supplied from time T3 is excited and turned into plasma. The plasma is supplied to the SiC layer formed on the wafer W. This makes it possible to form a highly pure SiC layer. Thereafter, at time T5, the supply of the H₂ gas and the application of the radio-frequency power are stopped.

In addition, the process of laminating the SiC film on the wafer W by supplying the BTMSA gas and the disilane gas into the processing container 10 in a parallel (simultaneous) manner and the process of supplying plasma to the SiC layer are repeated to form a SiC film. With this film forming method, it is also possible to laminate a highly pure SiC layer that is less likely to take in oxygen.

Here, by supplying plasma before the SiC layer becomes too thick, it is possible to ensure the elimination of functional groups and the bonding between dangling bonds even inside the SiC film. From this point of view, an interval of plasma processing may indicate a case where the thickness of the SiC layer is, for example, 1 nm or less.

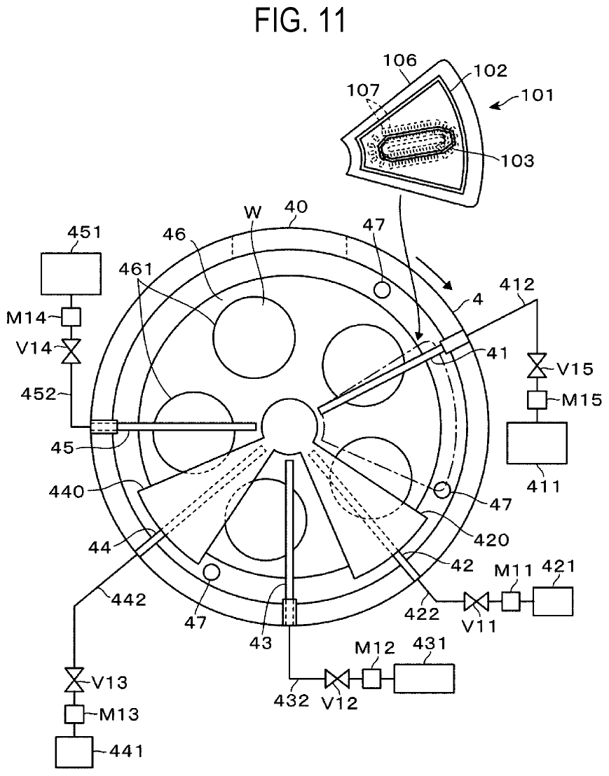

The film forming apparatus illustrated in FIG. 11 is an example of an apparatus for forming a SiC film by an ALD method in which a process of supplying a carbon precursor gas and a process of supplying a silicon precursor gas are alternately repeated. This film forming apparatus includes a processing container 4, which is made of a metal and is a vacuum container having a substantially circular shape in a plan view, and a rotary table 46, which serves as a stage made of, for example, quartz glass, and is configured to rotate the wafer W placed thereon.

The rotary table 46 is configured to be rotatable around a vertical axis at a rotational center coinciding with the center of the processing container 4. In a front surface of the rotary table 46, recesses 461 in which the wafers W are placed are provided at a plurality of locations (e.g., five locations) along the circumferential direction. A heater (not illustrated) is provided in a space between the rotary table 46 and a bottom surface of the processing container 4, and the wafer W is heated to a temperature lower than 500 degrees C., for example, a temperature in the range of 350 degrees C. to 400 degrees C. In FIG. 11, reference numeral 40 indicates a transfer port for the wafer W.

Various nozzles are disposed at positions facing regions through which the recesses 461 in the rotary table pass at intervals in the circumferential direction of the processing container 4. Specifically, a nozzle 41 for supplying a gas for plasma, for example, H₂, a nozzle 42 for supplying a separation gas, for example, a nitrogen (N₂) gas, a nozzle 43 for supplying a carbon precursor, for example, BTMSA, a nozzle 44 for supplying a separation gas, and a nozzle 45 for supplying a silicon precursor, for example, disilane. These nozzles 41 to 45 are provided sequentially clockwise when viewed from the transfer port 40. Each of the nozzles 41 to 45 is provided to extend from the outer peripheral wall of the processing container 4 toward the central portion thereof. A plurality of gas discharge holes are formed in a bottom surface of each of the nozzles 41 to 45.

Base end sides of these nozzles 41 to 45 are connected to sources 411, 421, 431, 441, and 451 of gases via supply paths 421, 422, 432, 442, and 452, respectively. The supply paths 412, 422, 432, 442, and 452 are provided with valves V11 to V15 and flow rate regulators M11 to M15, respectively. The carbon precursor supplier of this example includes the source 431 of BTMSA and the supply path 432. The silicon precursor supplier includes the source 451 of disilane and the supply path 452. In addition, the plasma gas supplier includes the source 411 of H₂ and the supply path 412. Convex portions 420 and 440 having a substantially fan-like shape in a plan view are provided above the nozzles 42 and 44, respectively, for supplying the separation gases. The separation gases (N₂ gas) discharged from the nozzles 42 and 44 are diffused from the respective nozzles 42 and 44 on opposite sides in the circumferential direction of the processing container 4, so that an atmosphere in which BTMSA is supplied and an atmosphere in which disilane is supplied are separated.

On the outer peripheral side of the rotary table 46, the downstream side of the nozzle 43 for supplying BTMSA, the downstream side of the nozzle 41 for supplying H₂, and the downstream side of the nozzle 45 for supplying disilane are provided with exhaust ports 47 to be spaced apart from each other in the circumferential direction. Each of the exhaust ports 47 is connected to an exhaust mechanism (not illustrated) via a metal-made vacuum exhaust path (not illustrated) provided with a pressure regulating valve.

A plasma generator 101 is provided above a region extending from the position of the nozzle 41 for supplying H₂ to the front side. As illustrated in FIG. 11, the plasma generator 101 is configured by winding an antenna 103 made of, for example, a metal wire, in a coil shape, and is accommodated in a housing 106 made of, for example, quartz. The antenna 103 is connected to a radio-frequency power supply (not illustrated) having a frequency of, for example, 13.56 MHz and output power of, for example, 5,000 W by a connecting electrode provided with a matcher (not illustrated). In the figure, reference numeral 102 indicates a Faraday shield that blocks an electric field generated from the radio-frequency generator, and reference numeral 107 indicates slits that allow a magnetic field generated from the plasma generator to reach the wafer W.

When forming the SiC film with this film forming apparatus, for example, five wafers W are placed on the rotary table 46, and an internal pressure of the processing container 4 is controlled to a predetermined pressure. Further, the rotary table 46 is rotated, the wafers W are heated to a temperature in the range of 350 degrees C. to 500 degrees C. by the heater, and the H₂ gas, BTMSA, disilane, and the N₂ gas are supplied from the nozzles 41 to 45, respectively. In addition, radio-frequency power is applied to the plasma generator 101. As a result, the H₂ gas supplied below the plasma generator 101 is turned into plasma. As the rotary table 46 rotates, the wafers W alternately pass through a BTMSA supply region to which BTMSA is supplied and a disilane supply region to which disilane is supplied. In the disilane supply region, since disilane needs to be thermally decomposed to generate SiH₂ radicals, the disilane supply region is secured to be wider than the BTMSA supply region so that the thermal decomposition of disilane proceeds sufficiently.

Then, the BTMSA gas is adsorbed on the surfaces of the wafers W in the BTMSA supply region. Subsequently, the generated SiH₂ radicals react with the BTMSA on the surfaces of the wafers W in the disilane supply region to form a SiC layer. In addition, H₂ plasma is supplied to the SiC layer to form a highly pure SiC layer. With the rotation of the rotary table 46 in this way, the process of supplying BTMSA to the wafers W, the process of supplying disilane to the surfaces of the wafers W on which BTMSA is adsorbed, and the process of supplying the H₂ plasma to the SiC layer are repeatedly performed in this order. As a result, the thermal reaction of these precursors proceeds on the surfaces of the wafers W to form a SiC film.

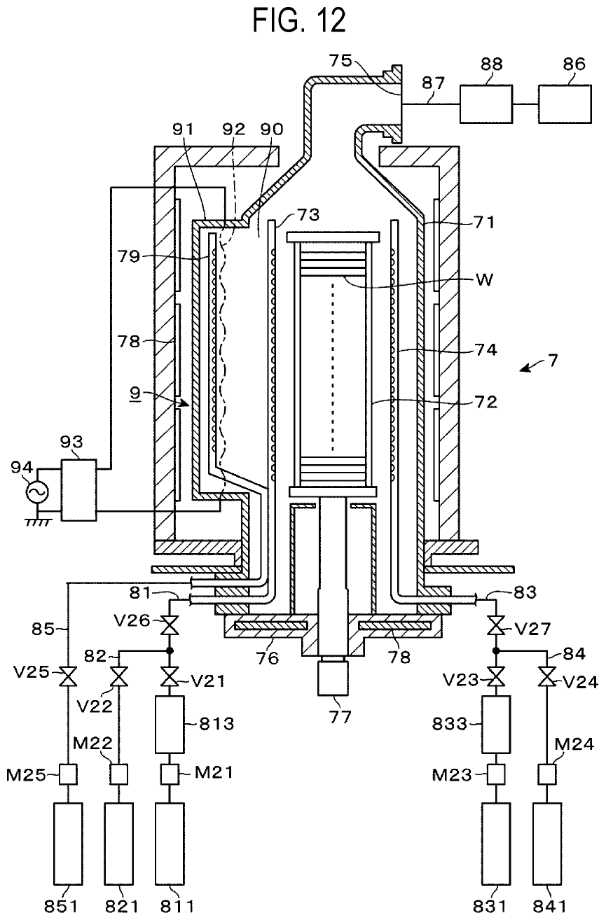

Next, as another embodiment of the film forming apparatus of the present disclosure, an example in which the film forming apparatus is configured by a batch-type vertical heat treatment apparatus will be briefly described with reference to FIG. 12. In a film forming apparatus 7, a wafer boat 72 into which a large number of wafers W are loaded in a shelf shape is airtightly accommodated inside a reaction tube 71, which is a processing container made of quartz glass, from the lower side. Inside the reaction tube 71, two gas injectors 73 and 74 are disposed to face each other across the wafer boat 72 in the length direction of the reaction tube 71.

The gas injector 73 is connected to, for example, a source 811 of a carbon precursor, for example, BTMSA gas, via a gas supply path 81. In addition, the gas injector 73 is connected to, for example, a source 821 of a purge gas, for example an Ar gas, via a branch path 82 branching from the gas supply path 81. The gas supply path 81 is provided with a flow rate regulator M21, a storage tank 813, and a valve V21 from the upstream side, and the branch path 82 is provided with a flow rate regulator M22 and a valve V22 from the upstream side. In this example, the carbon precursor supplier that supplies the carbon precursor gas to the reaction tube 71 includes the gas supply path 81 and the source 811 of the BTMSA gas.

The gas injector 74 is connected to, for example, a source 831 of a silicon precursor, for example, a disilane gas, via a gas supply path 83. In addition, the gas injector 74 is connected to, for example, a source 841 of an Ar gas as a purge gas via a branch path 84 branching from the gas supply path 83. The gas supply path 83 is provided with a flow rate regulator M23, a storage tank 833, and a valve V23 from the upstream side, and the branch path 84 is provided with a flow rate regulator M24 and a valve V24 from the upstream side. In this example, the silicon precursor supplier that supplies the silicon precursor gas to the reaction tube 71 includes the gas supply path 83 and the source 831 of the disilane gas.

An exhaust port 75 is formed in an upper end portion of the reaction tube 71. The exhaust port 75 is connected to a vacuum exhaust part 86 including a vacuum pump via a vacuum exhaust path 87 provided with an APC valve 88 which constitutes a pressure control valve.

In addition, an opening 90 is formed in a sidewall of the reaction tube 71. A plasma forming part 9 is provided outside the opening 90. The plasma forming part 9 includes a plasma forming box 91 that opens inward of the reaction tube 71. The plasma forming box 91 is provided with an antenna 92 that extends in the vertical direction from the upper end portion to the lower end portion of the plasma forming box 91. One end and the other end of the antenna 92 are connected to a grounded radio-frequency power supply 94 via a matcher 93.

In addition, a gas injector 79 extending in the vertical direction is provided inside the plasma forming box 91. The gas injector 79 is connected to, for example, a source 851 of a gas for plasma such as a H₂ gas via a gas supply path 85. The gas supply path 85 is provided with a flow rate regulator M25 and a valve V25 from the upstream side.

When radio-frequency power is supplied to the antenna 92 from the radio-frequency power supply 94, an electric field is formed around the antenna 92, and the H₂ gas ejected from the gas injector 79 into the plasma forming box 91 is turned into plasma by this electric field.

In FIG. 12, reference numeral 76 indicates a lid configured to open/close a lower end opening of the reaction tube 71, and reference numeral 77 indicates a rotation mechanism configured to rotate the wafer boat 72 around a vertical axis. Heaters 78 are provided around the reaction tube 71 and in the lid portion 76 to heat the wafers W loaded on the wafer boat 72 to a temperature in the range of, for example, 350 degrees C. or higher and 500 degrees C. or lower.

In this film forming apparatus 7 as well, it is possible to perform a film forming process of forming a SiC film by an ALD method or a CVD method, for example, according to the time chart illustrated in FIG. 4 or FIG. 10.

In an example in which the ALD method of FIG. 4 is executed, first, a process of loading the wafer boat 72, in which the plurality of wafers W are placed into the reaction tube 71, and closing the lid 76 of the reaction tube 71 to accommodate the wafers W into the reaction tube 71, is performed. Subsequently, the interior of the reaction tube 71 is evacuated, and in a state in which the valves V22 and V24 are opened to supply the Ar gas, the interior of the reaction tube 71 is controlled to have a pressure target value of, for example, 1,000 Pa, and to be at a set temperature of 350 degrees C. or higher and 500 degrees C. or lower, for example, 410 degrees C.

Next, BTMSA is adsorbed on the wafers W by performing a process of opening the valve V21 and supplying the BTMSA gas, which is a carbon precursor, into the reaction tube 71. Subsequently, after closing the valve V21 to stop the supply of the BTMSA gas, only the Ar gas is supplied to the reaction tube 71, and the interior of the reaction tube 71 is purged. Next, a process of opening the valve V23 and supplying the disilane gas, which is a silicon precursor, is performed to allow the BTMSA adsorbed on the wafer W to react with disilane so as to form a SiC film. Thereafter, after closing the valve V23 to stop the supply of the disilane gas, only the Ar gas is supplied to purge the interior of the reaction tube 71. By alternately repeating multiple times the process of adsorbing BTMSA and the process of allowing BTMSA to react with disilane, a SiC layer having a predetermined film thickness is formed.

Thereafter, the H₂ gas is ejected from the gas injector 79 and radio-frequency power is applied from the radio-frequency power supply 94. As a result, the H₂ gas is turned into plasma. The plasma is supplied to the SiC layer. By repeatedly performing the process of laminating the SiC film and the process of supplying the plasma to the SiC layer, it is possible to form a highly pure SiC film.

After performing the process of forming the SiC film, the internal pressure of the reaction tube 71 is restored to that at the time of loading/unloading of the wafers W, the lid 76 of the reaction tube 71 is opened, and the wafer boat 72 is lowered to unload the wafers W.

In this embodiment as well, the SiC film is formed by repeating: the process of laminating the SiC layer by repeatedly performing the process of supplying the BTMSA gas to the wafers W and the process of supplying the disilane gas; and the process of supplying the plasma to the SiC layer. As a result, it is possible to form a highly pure SiC layer. Thus, it is possible to form a SiC film that is difficult to oxidize.

The gas to be supplied as plasma in the process of supplying the plasma to the SiC layer may be a gas other than the H₂ gas. For example, by using an ammonia (NH₃) gas and an oxygen (O₂) gas as the gas to be supplied as plasma, it is possible to form a SiC film that is difficult to oxidize and contains O or N therein (SiCX film: X is N or O). In other words, it is possible to form a SiCN film or a SiOC film by incorporating O and N into a SiC film with excellent controllability while suppressing the influence of oxidization in an ambient environment.

At this time, when a NH₃ gas or a N₂ gas is selected as the gas to be supplied as plasma, it is possible to form a SiC film containing N therein (SiCN film). When an O₂ gas is selected as the gas to be supplied as plasma, it is possible to form a SiC film containing 0 therein (SiOC film).

Even in the example of forming such a SiCN film or a SiOC film, it is possible to form a SiC film that is difficult to oxidize (SiCN film or SiOC film) as illustrated in evaluation experiments to be described later.

The embodiments disclosed herein should be considered to be exemplary in all respects and not restrictive. The embodiments described above may be omitted, replaced, or modified in various forms without departing from the scope and spirit of the appended claims.

### Examples

### (Evaluation Experiment 1)

Evaluation experiments of the film forming method of the present disclosure will be described. In the film forming apparatus 1 illustrated in FIG. 1, BTMSA was used as the carbon precursor, disilane was used as the silicon precursor, the Ar gas was used as the purge gas, and the SiC film was formed by the ALD method illustrated in FIG. 4 in the same manner as in the embodiment. At this time, as illustrated in the embodiment, an example in which, each time the process of adsorbing BTMSA on the wafer W and the process of allowing BTMSA to react with disilane were repeated 16 times, the plasma of the H₂ gas was supplied to form a film having a thickness of 30 nm, is referred to as Example 1. The 16-time repetition of the process of adsorbing BTMSA on the wafer W and the process of allowing BTMSA to react with disilane corresponds to a film thickness of about 0.5 nm. Examples in which the supply of the plasma was performed each time the process of adsorbing BTMSA on the wafer W and the process of allowing BTMSA to react with disilane are repeated 8 times, 4 times, and 2 times, are referred to as Examples 2, 3, and 4, respectively.

Examples in which, after the SiC films were formed by Examples 1 to 4, an amorphous Si sealing film was formed on the surfaces of the SiC films with a film thickness of 20 nm, are referred to as Reference examples 1 to 4, respectively.

In addition, an example in which the SiC layer was processed in the same manner as in Reference examples except that plasma was not supplied to the SiC layer is referred to as Comparative example 1A, and an example in which the SiC layer was processed in the same manner as in Examples except that plasma was not supplied to the SiC layer is referred to as Comparative example 1B.

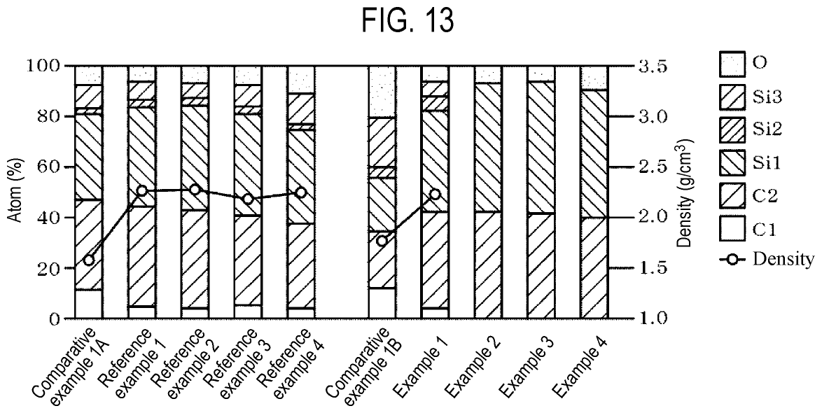

After forming the SiC film in each of Examples 1 to 4, Reference examples 1 to 4, and Comparative examples 1A and 1B, the SiC film was exposed to an ambient environment for a predetermined period of time, and then the components of the SiC film were analyzed by X-ray photoelectron spectroscopy (XPS). In Reference examples 1 to 4 and Comparative example 1A, after the SiC film is exposed to the ambient environment, the sealing film was removed by etching (sputtering with Ar), and the components of the SiC film were analyzed. FIG. 13 shows the results of the XPS analysis. In FIG. 13, O, C1, C2, Si1, Si2, and Si3 indicate the following components.
O: Oxygen atom
C1: Carbon atom having C—C bond and C—H bond
C2: Carbon atom having Si—C bond
Si1: Silicon atom having Si—C bond
Si2: Silicon atom having Si—Si bond
Si3: Silicon atom having SiOₓ

In addition, in each of Example 1, Reference examples 1 to 4, and Comparative examples 1A and 1B, the film density of the SiC film was measured.

As the results of the component analysis shown in FIG. 13, in Comparative example 1B, O atoms were detected at a proportion of about 21%, but in Examples 1 to 4, it was possible to suppress the proportions of O atoms to about 10%. Even in Comparative example 1A and Reference examples 1 to 4 in each of which the sealing film was formed above the SiC film, the proportions of 0 atoms were about 10%.

In terms of atomic compositions, in Comparative examples 1A and 1B, C based on Si—C bonds was detected at a proportion of 10% or more, but in Examples 1 to 4 and Reference examples 1 to 4, the proportions of C based on Si—C bonds were less than 10%. In Comparative examples 1A and 1B, the proportions of Si—C bonds (Si1+C2) were 69% and 43%, respectively, but in Examples 1 to 4 and Reference examples 1 to 4, the proportions were increased to 75% or more.

From this, it can be said that it is possible to form the SiC film to which oxygen is less likely to bond by the method of forming the silicon carbide-containing film according to the present disclosure. It is presumed that this is because functional groups and dangling bonds remaining in the film decreased and the proportion of Si—C bonds increased.

The film density of the SiC film was 1.58 g/cm³ and 1.86 g/cm³ in Comparative examples 1A and 1B, and 2.3 g/cm³ in Example 1. Even in Reference examples 1 to 4 in which the sealing films are formed, the film density of the SiC film was 2.19 to 2.28 g/cm³. Thus, it can be said that it is possible to increase the film density of the SiC film by the method of forming the silicon carbide-containing film according to the present disclosure.

### (Evaluation Experiment 2)

Next, an example in which the film was processed in the same manner as in Example 1 except that the film was formed by using the CVD method illustrated in FIG. 10 instead of the ALD method illustrated in FIG. 4 is referred to as Example 5. In Example 5, the SiC film having a film thickness of 30 nm was formed by performing plasma processing each time the SiC film is formed at a thickness of 4 nm.

In addition, examples in which the supply of plasma is performed each time SiC layers are formed at thicknesses of 2 nm, 1 nm, and 0.5 nm, respectively, are referred to as Examples 6 to 8, respectively. In addition, an example in which the flow rate of each gas when plasma is supplied to the SiC layer is set in the same manner as in Example 8 except that the flow rate of the H₂ gas is set to 50 sccm and the flow rate of the Ar gas is set to 2,250 sccm is referred to as Example 9. In addition, an example in which plasma is not supplied to the SiC layer is referred to as Comparative example 2. In Comparative example 2, an example in which the amorphous Si sealing film is formed on the surface of the SiC film after the film forming process is referred to as Comparative example 2A, and an example in which the sealing film is not formed is referred to as Comparative example 2B.

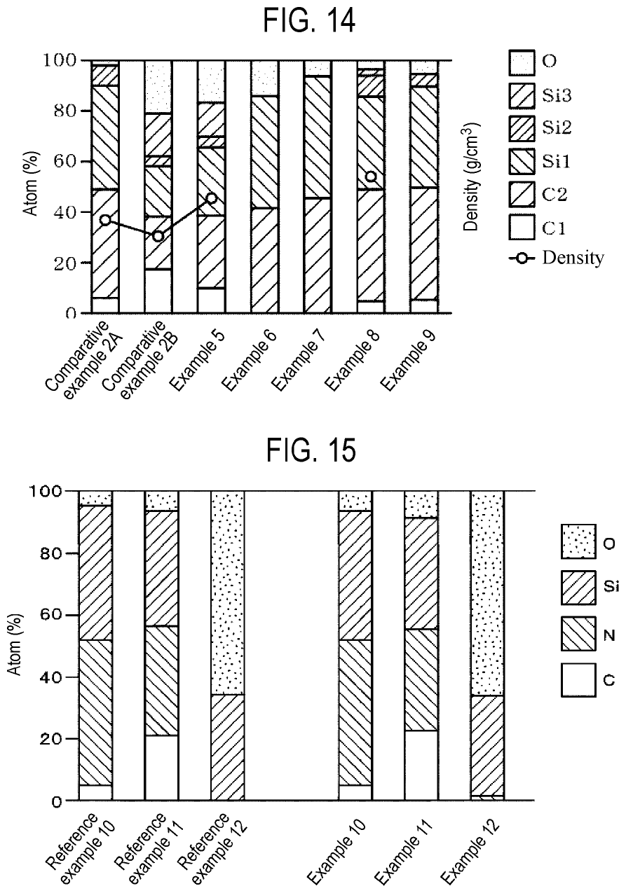

After forming the SiC film in each of Examples 5 to 9 and Comparative examples 2A and 2B, the SiC film was exposed to the ambient environment for a predetermined period of time, and then the components of the SiC film were analyzed by X-ray photoelectron spectroscopy (XPS). In Comparative example 2A, the components were analyzed after removing the sealing film by etching (sputtering with Ar). FIG. 14 shows the results of the XPS analysis. In FIG. 14, O, C1, C2, Si1, Si2, and Si3 indicate the same components as the legends indicated in FIG. 13.

As in the results of the component analysis shown in FIG. 14, in Comparative example 2A in which the sealing film is formed above the SiC film, 0 atoms were detected at a proportion of 1%, but in Comparative example 2B, O atoms were detected at a proportion of 20%. In Examples 5 to 8, it was possible to suppress the proportions of 0 atoms to 15% or less, and in Example 8, it was possible to reduce the proportion of 0 atoms to 3%. From this, it can be seen that even when the SiC film is formed by a CVD method, it is possible to form the SiC film that is difficult to oxidize by applying the film forming method according to the present disclosure.

In addition, the proportions of 0 atoms were low in both Examples 8 and 9 (3% and 4%, respectively). From this, a gas for plasma formation when plasma is supplied to the SiC film may have a large content of H₂ gas or a large content of Ar gas (noble gas).

### (Evaluation Experiment 3)

Further, Examples in which any of the NH₃ gas, the N₂ gas, and the O₂ gas was used as the gas to be turned into plasma and the process was performed in the same manner in Example 5 except that the supply of plasma is performed for 1 second each time the film forming process is performed for 30 seconds are referred to as Examples 10, 11, and 12, respectively. Examples in which, after the SiCX film is formed in each of Examples 10 to 12, the amorphous Si sealing film is formed on the surface of the SiCX film at a film thickness of 20 nm, are referred to as Reference examples 10 to 12, respectively.

After forming the SiC film in each of Examples 10 to 12 and Reference examples 10 to 12, the SiC film was exposed to the ambient environment for a predetermined period of time, and then the components of the SiC film (SiCX film) were analyzed by X-ray photoelectron Spectroscopy (XPS). In Reference examples 10 to 12, after exposure to the ambient environment, the sealing film was removed by etching (sputtering with Ar), and the components of the SiC film were analyzed. FIG. 15 shows the results of the XPS analysis. In FIG. 15, O, Si, N, and C represent atoms, respectively.

As in the results of component analysis shown in FIG. 15, in each of Examples 10 and 11, the SiC film containing a large amount of N (SiCN films) was formed. In Example 12, the SiC film containing a large amount of 0 and containing almost no C (SiOC film or SiO film) was formed. Under the conditions of Evaluation experiment 3 in which the O₂ gas in Example 12 was turned into plasma, the film contained almost no C. This is a result obtained since the conditions of the Evaluation experiment were matched with those of other gases to some extent. Under desired conditions, it is possible to form a SiC film containing O (SiOC film) with good controllability. The proportions of respective atoms in Examples 10 to 12 were almost the same as the proportions of respective atoms in Reference examples 10 to 12.

From this, it can be seen that it is possible to form a SiCX film in which components are less likely to change even when the sealing film is not formed on the surface of the SiCN film after the film forming process. Accordingly, it can be said that it is possible to form a SiCX film to which oxygen is less likely to bond by the method of forming the silicon carbide-containing film according to the present disclosure.

### (Evaluation Experiment 4)

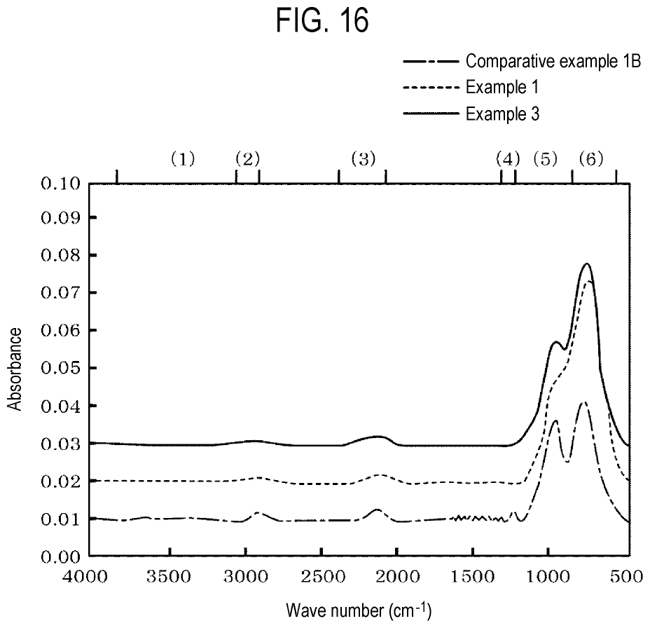

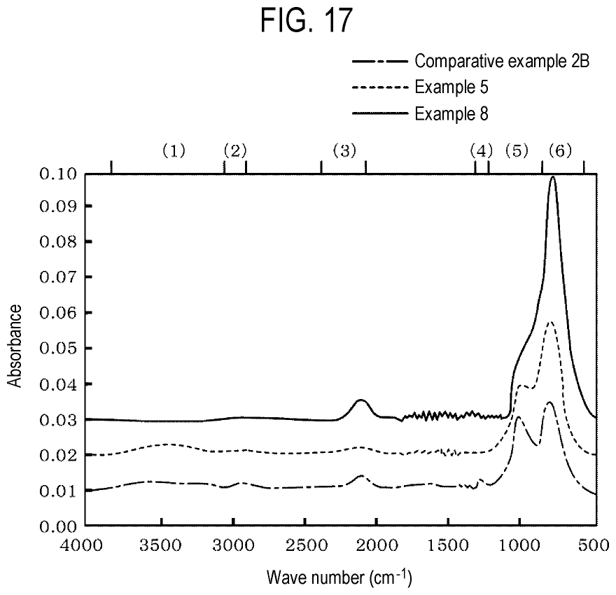

Next, for each wafer in Examples 1 and 3 and Comparative example 1B among the examples in which the film formation is performed by using the ALD method, and in Examples 5 and 8 and Comparative example 2B among the examples in which the film formation is performed by using the CVD method, the molecular structure was analyzed by measuring the absorbance of the SiC film by Fourier transform infrared spectroscopy (FT-IR). FIGS. 16 and 17 are a graph showing the absorbance with respect to the wave number of light in examples in which the film formation was performed by the ALD method, and a graph showing the absorbance with respect to the wave number of light in the examples in which the film formation was formed by the CVD method, respectively. The range of the wave number indicated by (1) to (6) in FIGS. 16 and 17 indicate the following vibrations.
(1): O—H stretching vibration
(2): C—H stretching vibration
(3): Si—H stretching vibration
(4): C—H bending vibration
(5): Si—O stretching vibration
(6): Si—C stretching vibration

As shown in FIGS. 16 and 17, in Comparative examples 1B and 2B, the peak of Si—O of (5) above and the peak of Si—C of (6) above were about the same, but in Examples 1, 3, 4, 5, and 8 in which plasma processing was performed, the peak of Si—O of (5) above decreased and the peak of Si—C of (6) above increased, so it can be said that the proportion of Si—C increases.

In addition, the peaks indicating the O—H stretching vibrations of (1) above disappeared by the plasma processing. It is presumed that the introduction of oxygen is suppressed. In Comparative examples, the peak appeared in the absorbance at the wave number indicating the C—H bending vibrations of (4) above. It is presumed that this is because in Comparative examples 1B and 2B, highly pure SiC was not formed, but functional groups such as C—H and —CH₃ were left in some places. It is presumed that oxygen is introduced into the SiC film or the film density is lowered due to the residual of such functional groups. In addition, it is presumed that by supplying plasma as in Examples, it is possible to promote the elimination of functional groups that deteriorate the properties of the SiC film and the bonding between unbonded films, thereby improving the film density and obtaining a film that is difficult to oxidize.

### EXPLANATION OF REFERENCE NUMERALS

W: semiconductor wafer, 8: RF power supply, 10: processing container, 2: stage, 51: source of carbon precursor, 52: source of silicon precursor, 55: source of gas for plasma

1-12. (canceled)

13. A method of forming a silicon carbide-containing film on a substrate, the method comprising:
heating the substrate;
supplying a carbon precursor gas containing an organic compound having an unsaturated carbon bond to the heated substrate;
supplying a silicon precursor gas containing a silicon compound to the heated substrate;
laminating, on the substrate, a silicon carbide-containing layer to be turned into the silicon carbide-containing film by allowing the organic compound having the unsaturated carbon bond to thermally react with the silicon compound; and
supplying plasma to the silicon carbide-containing layer.

14. The method of claim 13, wherein the laminating the silicon carbide-containing layer on the substrate is carried out by repeating multiple times the supplying the carbon precursor gas and the supplying the silicon precursor in an alternate manner, and
wherein the silicon carbide-containing film is formed by repeating multiple times the laminating the silicon carbide-containing layer on the substrate and the supplying the plasma to the silicon carbide-containing layer in an alternate manner.

15. The method of claim 13, wherein the laminating the silicon carbide-containing layer on the substrate is carried out by performing the supplying the carbon precursor gas and the supplying the silicon precursor gas in a parallel manner, and
the silicon carbide-containing film is formed by repeating multiple times the laminating the silicon carbide-containing layer on the substrate and the supplying the plasma to the silicon carbide-containing layer in an alternate manner.

16. The method of claim 14, wherein, in the repeating multiple times the laminating the silicon carbide-containing layer on the substrate and the supplying the plasma to the silicon carbide-containing layer, a thickness of the silicon carbide-containing layer formed in the laminating the silicon carbide-containing layer on the substrate at one time is 1 nm or less.

17. The method of claim 16, wherein the plasma is obtained by exciting one plasma forming gas selected from a hydrogen gas, an ammonia gas, a nitrogen gas, an oxygen gas, a noble gas, or a mixed gas of at least one of the hydrogen gas, the ammonia gas, the nitrogen gas, and the oxygen gas and the noble gas.

18. The method of claim 17, wherein the substrate is heated at a temperature in a range of less than 500 degrees C.

19. The method of claim 15, wherein, in the repeating multiple times the laminating the silicon carbide-containing layer on the substrate and the supplying the plasma to the silicon carbide-containing layer, a thickness of the silicon carbide-containing layer formed in the laminating the silicon carbide-containing layer on the substrate at one time is 1 nm or less.

20. The method of claim 13, wherein the plasma is obtained by exciting one plasma forming gas selected from a hydrogen gas, an ammonia gas, a nitrogen gas, an oxygen gas, a noble gas, or a mixed gas of at least one of the hydrogen gas, the ammonia gas, the nitrogen gas, and the oxygen gas and the noble gas.

21. The method of claim 13, wherein the substrate is heated at a temperature in a range of less than 500 degrees C.

22. An apparatus for forming a silicon carbide-containing film on a substrate, comprising:
a processing container configured to accommodate the substrate;
a heater configured to heat the substrate accommodated in the processing container;
a carbon precursor supplier configured to supply a carbon precursor gas containing an organic compound having an unsaturated carbon bond to the processing container;
a silicon precursor supplier configured to supply a silicon precursor gas containing a silicon compound to the processing container;
a plasma forming part configured to form plasma inside the processing container by exciting a gas for plasma; and
a controller,
wherein the controller is configured to execute steps of:
heating the substrate accommodated in the processing container;
supplying the carbon precursor gas containing the organic compound having the unsaturated carbon bond to the heated substrate inside the processing container;
supplying the silicon precursor gas containing the silicon compound to the heated substrate inside the processing container;
laminating, on the substrate, a silicon carbide-containing layer to be turned into the silicon carbide-containing film by allowing the organic compound having the unsaturated carbon bond to thermally react with the silicon compound; and
forming the plasma inside the processing container and supplying the plasma to the silicon carbide-containing layer.

23. The apparatus of claim 22, wherein the controller is configured to execute:
in the step of laminating the silicon carbide-containing layer on the substrate, repeating multiple times the step of supplying the carbon precursor gas and the step of supplying the silicon precursor in an alternate manner, and
forming the silicon carbide-containing film by repeating multiple times the step of laminating the silicon carbide-containing layer on the substrate and the step of supplying the plasma to the silicon carbide-containing layer in an alternate manner.

24. The apparatus of claim 22, wherein the controller is configured to execute:
in the step of laminating the silicon carbide-containing layer on the substrate, the step of supplying the carbon precursor gas and the step of supplying the silicon precursor gas in a parallel manner; and
forming the silicon carbide-containing film by repeating multiple times the step of laminating the silicon carbide-containing layer on the substrate and the step of supplying the plasma to the silicon carbide-containing layer in an alternate manner.

25. The apparatus of claim 23, wherein, in the repeating multiple times the step of laminating the silicon carbide-containing layer on the substrate and the step of supplying the plasma to the silicon carbide-containing layer, a thickness of the silicon carbide-containing layer formed in the step of laminating the silicon carbide-containing layer on the substrate at one time is 1 nm or less.

26. The apparatus of claim 25, wherein the plasma is obtained by exciting one plasma forming gas selected from a hydrogen gas, an ammonia gas, a nitrogen gas, an oxygen gas, a noble gas, or a mixed gas of at least one of the hydrogen gas, the ammonia gas, the nitrogen gas, and the oxygen gas and the noble gas.

27. The apparatus of claim 26, wherein the substrate is heated at a temperature in a range of less than 500 degrees C.

28. The apparatus of claim 24, wherein, in the repeating multiple times the step of laminating the silicon carbide-containing layer on the substrate and the step of supplying the plasma to the silicon carbide-containing layer, a thickness of the silicon carbide-containing layer formed in the step of laminating the silicon carbide-containing layer on the substrate at one time is 1 nm or less.

29. The apparatus of claim 22, wherein the plasma is obtained by exciting one plasma forming gas selected from a hydrogen gas, an ammonia gas, a nitrogen gas, an oxygen gas, a noble gas, or a mixed gas of at least one of the hydrogen gas, the ammonia gas, the nitrogen gas, and the oxygen gas and the noble gas.

30. The apparatus of claim 22, wherein the substrate is heated at a temperature in a range of less than 500 degrees C.
